(19) United States
(12) Patent Application Publication
(10) Pub. No.: US 2018/0219097 A1
(43) Pub. Date: Aug. 2, 2018

(54) SEMICONDUCTOR DEVICE AND METHOD FOR MANUFACTURING SAME

(71) Applicant: Sharp Kabushiki Kaisha, Sakai City, Osaka (JP)

(72) Inventor: Takatoshi ORUI, Sakai City (JP)

(21) Appl. No.: 15/747,773

(22) PCT Filed: Jul. 19, 2016
(86) PCT No.: PCT/JP2016/071141

§ 371 Date: Jan. 26, 2018

(30) Foreign Application Priority Data
Jul. 27, 2015 (JP) 2015-147993

(51) Int. Cl. H01L 29/786; H01L 27/12; H01L 29/66; H01L 21/02

(52) U.S. Cl. CPC H01L 29/7869; H01L 29/78696; H01L 27/1225; G02F 1/134363; H01L 21/02565; H01L 21/0257; H01L 21/02631; H01L 29/66969

(57) ABSTRACT

A semiconductor device (101) includes: an oxide semiconductor layer (5) supported on a substrate (1), the oxide semiconductor layer (5) having a first principal face and a second principal face opposite to each other; and a first dielectric layer (9) disposed in contact with the first principal face of the oxide semiconductor layer (5). The oxide semiconductor layer (5) has a multilayer structure that includes a main layer (5c) containing substantially no halogen element and a first halogen element-containing oxide semiconductor layer (51) containing a halogen element, the first halogen element-containing oxide semiconductor layer (51) being interposed between the main layer (50) and the first dielectric layer (9).

### TECHNICAL FIELD

The present invention relates to a semiconductor device which is produced by using an oxide semiconductor, and a method of producing the same.

### BACKGROUND ART

Active matrix substrates that are used for liquid crystal display devices or the like include a switching element for each pixel, e.g., a thin film transistor (hereinafter “TFT”). As such switching elements, TFTs whose active layer is an amorphous silicon film (hereinafter “amorphous silicon TFTs”) and TFTs whose active layer is a polycrystalline silicon film (hereinafter “polycrystalline silicon TFTs”) have been widely used.

In the recent years, it has been proposed to use an oxide semiconductor as the material of the active layers of TFTs, instead of an amorphous silicon or a polycrystalline silicon. These TFTs are called “oxide semiconductor TFTs”. An oxide semiconductor provides a higher mobility than does an amorphous silicon. Therefore, oxide semiconductor TFTs can operate more rapidly than amorphous silicon TFTs. Moreover, an oxide semiconductor film is formed through a simple process as compared to a polycrystalline silicon film, and therefore is applicable to devices which require a large geometric area.

In a semiconductor device having oxide semiconductor TFTs, the state of the oxide semiconductor layer may change because of films that are in contact with the oxide semiconductor layer, the fabrication process, or the like. For example, impurities such as moisture may diffuse into the oxide semiconductor layer from a protective dielectric film to create an impurity level, or oxygen may diffuse from the oxide semiconductor layer into another layer to cause oxygen defects in the oxide semiconductor layer, thus resulting in a higher carrier density. When the electronic state, carrier density, or the like of the oxide semiconductor layer changes, the TFT characteristics will fluctuate, possibly detracting from reliability.

On the other hand, it has been proposed to utilize halogen elements to suppress changes in the state of an oxide semiconductor layer that are ascribable to the aforementioned impurity level and oxygen defects. Patent Document 1 proposes subjecting an oxide semiconductor layer to a plasma treatment in a gas ambient that contains a halogen element so that the halogen element will adhere to the upper face of the oxide semiconductor layer, thus forming a surface layer containing the halogen element. Moreover, Patent Document 2 proposes a construction where a halogen element is allowed to be contained in a dielectric layer that comes in contact with an oxide semiconductor layer.

### CITATION LIST

### Patent Literature

[Patent Document 1] Japanese Laid-Open Patent Publication No. 2013-41949

[Patent Document 2] Japanese Laid-Open Patent Publication No. 2013-38428

### SUMMARY OF INVENTION

### Technical Problem

However, according to a study by the inventor, the method in which a halogen element is allowed to adhere to the upper face of the oxide semiconductor layer through plasma treatment may induce device destruction, charge-up, etc., due to the plasma treatment, possibly causing fluctuations in the TFTs. Furthermore, since the halogen element cannot adhere to the lower face of the oxide semiconductor layer, there is also a problem of being unable to suppress formation of oxygen defects in the lower portion of the oxide semiconductor layer.

On the other hand, depending on the fabrication process, the method in which a dielectric layer containing a halogen element is formed may not be able to sufficiently suppress changes in the state of the oxide semiconductor layer.

The present invention has been made in view of the above circumstances, and an objective thereof is to, in a semiconductor device including an oxide semiconductor layer, keep the state of the oxide semiconductor layer more stable and enhance reliability.

### Solution to Problem

A semiconductor device according to an embodiment of the present invention comprises: a substrate; an oxide semiconductor layer supported on the substrate, the oxide semiconductor layer having a first principal face and a second principal face opposite to each other; and a first dielectric layer disposed in contact with the first principal face of the oxide semiconductor layer, wherein the oxide semiconductor layer has a multilayer structure that includes a main layer containing substantially no halogen element and a first halogen element-containing oxide semiconductor layer containing a halogen element, the first halogen element-containing oxide semiconductor layer being interposed between the main layer and the first dielectric layer.

In one embodiment, the semiconductor device further comprises a second dielectric layer disposed in contact with the second principal face of the oxide semiconductor layer, wherein the second dielectric layer includes a halogen element-containing dielectric layer containing a halogen element.

In one embodiment, the semiconductor device further comprises a second dielectric layer which is disposed in contact with the second principal face of the oxide semiconductor layer, wherein the multilayer structure of the oxide semiconductor layer further includes a second halogen element-containing oxide semiconductor layer containing a halogen element, the second halogen element-containing oxide semiconductor layer interposed between the main layer and the second dielectric layer.

In one embodiment, the semiconductor device further comprises: a thin film transistor having the oxide semiconductor layer as an active layer; and a passivation layer which covers the thin film transistor, wherein the first dielectric layer is the passivation layer; and the second dielectric layer is a gate dielectric layer of the thin film transistor.

In one embodiment, the semiconductor device further comprises: a thin film transistor having the oxide semiconductor layer as an active layer; and a passivation layer which covers the thin film transistor, wherein, the first dielectric layer is a gate dielectric layer of the thin film transistor; and the second dielectric layer is the passivation layer.

The first halogen element-containing oxide semiconductor layer may have a halogen element concentration which is greater than 1×10¹⁸/cm³ but not greater than 1×10²⁰/cm³.

The main layer of the oxide semiconductor layer may have a halogen element concentration which is not more than 10¹⁶/cm³.

The first halogen element-containing oxide semiconductor layer may have a thickness which is not less than 5 nm and not more than 30 nm.

In one embodiment, the above semiconductor device further comprises a thin film transistor having the oxide semiconductor layer as an active layer, wherein the thin film transistor has a channel etch structure.

The oxide semiconductor layer may comprise an In—Ga—Zn—O type semiconductor.

The oxide semiconductor layer may include a crystalline portion.

A method of producing a semiconductor device according to an embodiment of the present invention comprises: (A) a step of providing a substrate having a dielectric layer on a surface; (B) a step of forming an oxide semiconductor layer so as to be in contact with the dielectric layer; and (C) a step of forming another dielectric layer so as to be in contact with an upper face of the oxide semiconductor layer, wherein, the oxide semiconductor layer has a multilayer structure that includes a main layer containing substantially no halogen element and a halogen element-containing oxide semiconductor layer containing a halogen element; and step (B) comprises step (B1) of forming the main layer by a sputtering technique using a target containing a metal or a metal oxide, and step (B2), which is performed before or after step (B1), of forming the halogen element-containing oxide semiconductor layer by a sputtering technique using the target while supplying a gas containing the halogen element to the substrate.

In one embodiment, step (B2) is performed after step (B1); and step (A) comprises a step of forming a halogen element-containing dielectric layer containing a halogen element.

In one embodiment, step (B2) is performed before step (B1); and step (C) comprises a step of forming a halogen element-containing dielectric layer containing a halogen element.

In one embodiment, step (B2) is performed before step (B1); step (B) further comprises step (B3) of forming, after step (B1), another halogen element-containing oxide semiconductor layer containing a halogen element by a sputtering technique using the target while supplying a gas containing the halogen element to the substrate; and the multilayer structure of the oxide semiconductor layer includes the halogen element-containing oxide semiconductor layer, the main layer, and the other halogen element-containing oxide semiconductor layer in this order.

In one embodiment, the semiconductor device comprises a thin film transistor having the oxide semiconductor layer as an active layer.

In one embodiment, the thin film transistor has a channel etch structure.

The oxide semiconductor layer may comprise an In—Ga—Zn—O type semiconductor.

The oxide semiconductor layer may include a crystalline portion.

### Advantageous Effects of Invention

According to an embodiment of the present invention, in a semiconductor device including an oxide semiconductor layer, it is possible to keep the state of the oxide semiconductor layer more stable and enhance reliability.

### BRIEF DESCRIPTION OF DRAWINGS

FIG. 1 A schematic cross-sectional view illustrating a semiconductor device 101 according to a first embodiment.

FIG. 2 A schematic cross-sectional view illustrating a semiconductor device 102 according to a second embodiment.

FIG. 3 A schematic cross-sectional view illustrating a semiconductor device 103 according to a third embodiment.

FIG. 4 (a) to (c) are graphs showing current-voltage characteristics before and after a PBTI test in TFTs according to Comparative Example and Examples 1 and 2, respectively.

FIG. 5 A schematic cross-sectional view illustrating a TFT structure according to another embodiment.

FIG. 6 A schematic cross-sectional view illustrating a TFT structure according to still another embodiment.

FIG. 7 A schematic plan view showing an exemplary planar structure of an active matrix substrate 700 according to a fourth embodiment.

FIG. 8 A cross-sectional view of a crystalline silicon TFT 710A and an oxide semiconductor TFT 710B in the active matrix substrate 700.

### DESCRIPTION OF EMBODIMENTS

As described above, with the method of subjecting an oxide semiconductor layer to a plasma treatment so that a halogen element will adhere to the surface of the oxide semiconductor layer, it may be difficult to sufficiently enhance the reliability of the semiconductor device.

On the other hand, the inventor have found that, by forming an oxide semiconductor layer with a multilayer film that includes an oxide semiconductor film containing substantially no halogen element and an oxide semiconductor film containing a halogen element, it becomes possible, without performing a plasma treatment, to suppress fluctuations in the TFT characteristics that are ascribable to oxygen defects or the like, thereby arriving at the present invention.

A semiconductor device according to an embodiment of the present invention includes: an oxide semiconductor layer supported on a substrate; and a first dielectric layer disposed in contact with one surface (first principal face) of the oxide semiconductor layer. The oxide semiconductor layer has a multilayer structure that includes a main layer containing no halogen element and a first halogen element-containing oxide semiconductor layer containing a halogen element. The first halogen element-containing oxide semiconductor layer is disposed on the first dielectric layer side of the main layer. The oxide semiconductor layer may be an active layer of a TFT, with a channel of the TFT being formed in the main layer of the oxide semiconductor layer. The first dielectric layer may be a gate dielectric layer, a passivation layer covering the TFT, an etchstop layer, underlying dielectric layer, or the like.

In such a construction, the halogen element is able to terminate an impurity level that has occurred in the oxide semiconductor layer, and compensate for oxygen defects. As a result, the impurity level and oxygen defects that may occur because of the oxide semiconductor layer being in contact with the first dielectric layer can be reduced, whereby a semiconductor device with high reliability can be provided.

A dielectric layer (second dielectric layer) may also be formed on a principal face (second principal face) of the oxide semiconductor layer that is opposite to the first principal face. In this case, the oxide semiconductor layer may further include a second halogen element-containing oxide semiconductor layer on the second dielectric layer side of the main layer. Alternatively, the second dielectric layer may include a layer containing a halogen element. When a halogen element is thus added to both layers above and below the main layer, influences of distributed halogen element concentration within the oxide semiconductor layer can be reduced relative to the case where a halogen element is added to only one of layers above and below the main layer. As a result, the halogen element-based effect of reducing the impurity level and oxygen defects is obtained uniformly across the entire main layer.

Now, the aforementioned effects from the halogen element will be described in more detail.

When impurities containing hydrogen atoms (hydrogen and hydroxy groups) diffuse from the first dielectric layer into the oxide semiconductor layer, the impurities will bind with a metal in the oxide semiconductor, thus creating an impurity level. In the present embodiment, the oxide semiconductor layer contains a halogen element. A halogen element has a high binding energy with hydrogen atoms, and thus binds stronger with impurities that contain hydrogen atoms. Therefore, the impurities which have diffused into the oxide semiconductor layer can be converted by the halogen element into more stable substances. As a result, an impurity level is restrained from occurring in the oxide semiconductor.

Moreover, when oxygen defects are formed in the oxide semiconductor layer to cause loss of metal-oxygen bonds, dangling bonds (incomplete bonds) will occur. This may create an impurity level, or cause fluctuations in carrier density, possibly reducing reliability. In the present embodiment, the halogen element will terminate the dangling bonds, so that fewer dangling bonds will occur in the oxide semiconductor.

Furthermore, during the fabrication process, e.g., at a heat treatment or when stress with light or voltage is applied, the halogen element will diffuse to the main layer, so that the impurity level and oxygen defects can be effectively restrained from occurring inside the main layer of the oxide semiconductor layer and at interfaces between the main layer and the first and second dielectric layers (especially at the interface between the main layer and the first dielectric layer). Moreover, the halogen element can bind with the hydrogen-based impurities contained in the first dielectric layer, thus restraining the impurities from diffusing into the oxide semiconductor layer.

Note that a semiconductor device according to an embodiment of the present invention may at least include an oxide semiconductor layer, and broadly encompasses: semiconductor elements such as TFTs and thin film diodes (TFD); active matrix substrates; various display devices; electronic devices; and so on.

### First Embodiment

Hereinafter, with reference to the drawings and by taking an oxide semiconductor TFT (hereinafter simply referred to as a “TFT”) as an example, a first embodiment of a semiconductor device according to the present invention will be described. Although a bottom-gate TFT of the top-contact type will be illustrated as the TFT herein, there is no particularly limitation as to the structure of the TFT.

FIG. 1 is a schematic cross-sectional view illustrating a semiconductor device 101.

The semiconductor device 101 includes a substrate 1, a TFT 10 formed on the substrate 1, and a passivation layer 9 covering the TFT 10.

The TFT 10 may be a channel-etch type TFT, for example. The TFT 10 includes a gate electrode 3 supported on the substrate 1, a gate dielectric layer 4 covering the gate electrode 3, an oxide semiconductor layer 5 disposed so as to overlap the gate electrode 3 via the gate dielectric layer 4, a source electrode 7s, and a drain electrode 7d.

The oxide semiconductor layer 5 has a channel region 5c, and a source contact region 5s and a drain contact region 5d which are located on both sides of the channel region. The source electrode 7s is formed in contact with the source contact region 5s, whereas the drain electrode 7d is formed in contact with the drain contact region 5d. The source electrode 7s and the drain electrode 7d may be made of the same multilayer film.

The oxide semiconductor layer 5 has two principal faces (an upper face and a lower face) opposite to each other. In the semiconductor device 101, one principal face (upper face) of the oxide semiconductor layer 5 is in contact with the passivation layer 9, whereas the other principal face (lower face) is in contact with the gate dielectric layer 4.

The oxide semiconductor layer 5 according to the present embodiment has a multilayer structure that includes a main layer 50 containing substantially no halogen element and a first halogen element-containing oxide semiconductor layer 51 formed between the main layer 50 and the passivation layer 9. The main layer 50 includes a channel region 5c in which a channel is to be formed, thus being capable of functioning as an active region of the TFT.

The first halogen element-containing oxide semiconductor layer 51 is an oxide semiconductor layer containing a halogen element. Although not particularly limited, the halogen element may be fluorine, chlorine, or the like, for example. Two or more kinds of halogen elements may be contained. As their main components, the main layer and the first halogen element-containing oxide semiconductor layer 51 may contain oxide semiconductors that contain the same metallic element. For example, each of the main layer 50 and the first halogen element-containing oxide semiconductor layer 51 may mainly contain an oxide semiconductor that contains In, Ga, and Zn. Alternatively, the oxide semiconductors of the main layer 50 and the first halogen element-containing oxide semiconductor layer 51 may differ from each other with respect to their types, compositions, crystal states, or the like.

In the present specification, a “layer containing substantially no halogen element” is a layer which has been formed under conditions that are free of halogen elements, and, even though it may not have contained any halogen elements immediately after the film formation, it may occasionally contain a minute amount of halogen element that has diffused from another layer that is in contact therewith. The halogen element concentration in a layer containing substantially no halogen element may be e.g. not less than 0/cm³ and not more than 10¹⁶/cm³. As used herein, a “halogen element-containing oxide semiconductor layer” refers to a layer in which a halogen element is present across its thickness direction, and does not encompass a layer having a halogen element adhering to its upper face (i.e., an oxide semiconductor layer having a surface layer that is composed of a halogen element) such as is described in Patent Document 1.

The gate dielectric layer 4 may have a multilayer structure that includes a lower layer 40 containing substantially no halogen element and a halogen element-containing dielectric layer 41 which is formed between the lower layer 40 and the oxide semiconductor layer 5. Although not particularly limited, the halogen element may be fluorine, chlorine, or the like, for example. The halogen element-containing dielectric layer 41 may contain two or more kinds of halogen elements. The halogen element(s) to be contained in the halogen element-containing dielectric layer 41 may be the same as, or different from, the aforementioned halogen element that is contained in the first halogen element-containing oxide semiconductor layer 51.

The lower layer 40 and the halogen element-containing dielectric layer 41 may contain the same electrically insulating material as their main components. For example, the lower layer and the halogen element-containing dielectric layer 41 may both mainly contain silicon oxide (SiOx) or silicon nitride (SiNx).

According to the present embodiment, the halogen element(s) contained in the first halogen element-containing oxide semiconductor layer 51 or the halogen element-containing dielectric layer 41 can terminate an impurity level that occurs in the oxide semiconductor layer 5 (especially in the main layer 50), thus compensating for oxygen defects. This allows to suppress fluctuations in the TFT characteristics, and enhance reliability of the TFT 10.

For example, the method (Patent Document 1) where halogen elements are allowed to adhere to the surface of the oxide semiconductor layer through plasma treatment may not be able to sufficiently reduce the oxygen defects that occur in the lower portion of the oxide semiconductor layer. In contrast, according to the present embodiment, the halogen element diffuses from the first halogen element-containing oxide semiconductor layer 51 toward the upper face of the main layer 50 of the oxide semiconductor layer 5, whereas the halogen element(s) from the halogen element-containing dielectric layer 41 diffuses toward the lower face of the main layer 50. This allows to effectively suppress fluctuations in the TFT characteristics that may arise because of the upper face and the lower face of the oxide semiconductor layer being in contact with the dielectric layers (the gate dielectric layer 4 and the passivation layer 9). Moreover, since the present embodiment does not perform a plasma treatment for causing adhesion of the halogen element(s), device destruction or the like associated with such treatment can be suppressed.

Furthermore, the first halogen element-containing oxide semiconductor layer 51 may be successively formed immediately after forming the main layer 50. Therefore, in a production step such as a patterning step for source-drain separation, etching damage to the main layer 50 and defect formation due to mixing of impurities can be suppressed.

The halogen element concentrations in the first halogen element-containing oxide semiconductor layer 51 and the halogen element-containing dielectric layer 41 are preferably greater than e.g. 1×10¹⁸/cm³, and more preferably, 2.5×10¹⁸ cm/³ or greater. This allows occurrence of the impurity level and oxygen defects in the oxide semiconductor layer 5 to be suppressed more effectively. On the other hand, as the halogen element concentration in the first halogen element-containing oxide semiconductor layer 51 increases, the first halogen element-containing oxide semiconductor layer 51 will increase in resistance, possibly increasing the ON resistance. As the halogen element concentration in the halogen element-containing dielectric layer 41 increases, there will be increased formation of hot carriers and breakdown. Therefore, the halogen element concentration is set to e.g. 1×10²⁰/cm³ or smaller, and preferably 5×10¹⁹ cm/³ or smaller. As used herein, a halogen element concentration is an average concentration in a layer containing a halogen element, which may be measured by e.g. secondary ion mass spectrometry (SIMS).

The oxide semiconductor layer 5 may have a two-layer structure that includes the main layer 50 and the first halogen element-containing oxide semiconductor layer 51, or a structure of three or more layers including these layers. For example, the main layer 50 containing substantially no halogen element may include a plurality of oxide semiconductor layers differing with respect to their compositions, crystal states, or the like. The first halogen element-containing oxide semiconductor layer 51 may constitute the upper face (first principal face) of the oxide semiconductor layer 5, thus being in contact with the passivation layer 9. This will suppress changes in the state of the main layer 50 that are associated with the passivation layer 9 more effectively.

Although not particularly limited, the thickness of the first halogen element-containing oxide semiconductor layer 51 is set to be smaller than the thickness of the main layer 50, for example. The thickness of the first halogen element-containing oxide semiconductor layer 51 may be e.g. not less than 5 nm and not more than 30 nm. If it is less than 5 nm, less than an adequate effect of halogen element addition may be obtained because of the surface roughness of the oxide semiconductor layer 5, pinholes, and other influences. On the other hand, if the thickness of the first halogen element-containing oxide semiconductor layer 51 exceeds 30 nm, the first halogen element-containing oxide semiconductor layer 51 may become high in resistance to deteriorate the ON current, such that a sufficient on/off ratio may not be obtained.

The gate dielectric layer 4 may at least include the halogen element-containing dielectric layer 41; it may have a two-layer structure including the lower layer 40 and the halogen element-containing dielectric layer 41, or a structure of three or more layers including these layers. Alternatively, the gate dielectric layer 4 may have a single-layer structure that is composed only of the halogen element-containing dielectric layer 41. The halogen element-containing dielectric layer 41 may constitute an upper face of the gate dielectric layer 4, thus being in contact with the oxide semiconductor layer 5. This will suppress changes in the state of the main layer 50 that are associated with the gate dielectric layer 4 more effectively.

Although not particularly limited, the thickness of the halogen element-containing dielectric layer 41 is set to be smaller than the thickness of the lower layer 40, for example. The thickness of the halogen element-containing dielectric layer 41 may be e.g. not less than 50 nm and not more than 500 nm. When the thickness is 50 nm or more, oxygen defects and the like occurring in the oxide semiconductor layer 5 can be reduced more effectively.

Now, the oxide semiconductor layer 5 to be used in the present embodiment will be described. The oxide semiconductor that is contained in the oxide semiconductor layer 5 may be an amorphous oxide semiconductor film, or a crystalline oxide semiconductor having a crystalline portion(s). Examples of crystalline oxide semiconductors may include polycrystalline oxide semiconductors, microcrystalline oxide semiconductors, and crystalline oxide semiconductors whose c axis is oriented generally perpendicular to the layer plane.

The oxide semiconductor layer 5 may have a multilayer structure of two or more layers. When the oxide semiconductor layer 5 has a multilayer structure, the oxide semiconductor layer 5 may include an amorphous oxide semiconductor layer and a crystalline oxide semiconductor layer. Alternatively, a plurality of crystalline oxide semiconductor layers with different crystal structures may be included. Moreover, a plurality of amorphous oxide semiconductor layers may be included. In the case where the oxide semiconductor layer 5 has a two-layer structure including an upper layer and a lower layer, it is preferable that the oxide semiconductor that is contained in the upper layer has an energy gap which is greater than the energy gap of the oxide semiconductor that is contained in the lower layer. However, when the difference between the energy gaps of these layers is relatively small, the energy gap of the oxide semiconductor of the lower layer may be greater than the energy gap of the oxide semiconductor of the upper layer. In the present embodiment, the upper layer (or the lower layer) of the oxide semiconductor layer 5 having a multilayer structure may function as a halogen element-containing oxide semiconductor layer. Alternatively, the main layer 50 of the oxide semiconductor layer 5 may have such a multilayer structure.

Materials, structures, film formation methods, and the like of amorphous oxide semiconductors and the aforementioned crystalline oxide semiconductors, the construction of an oxide semiconductor layer having a multilayer structure, and the like are described in Japanese Laid-Open Patent Publication No. 2014-007399, for example. The entire disclosure of Japanese Laid-Open Patent Publication No. 2014-007399 is incorporated herein by reference.

The oxide semiconductor layer 5 may contain at least one metallic element among In, Ga, and Zn, for example. In the present embodiment, the oxide semiconductor layer 5 contains an In—Ga—Zn—O type semiconductor (e.g., indium gallium zinc oxide), for example. Herein, the In—Ga—Zn—O type semiconductor is a ternary oxide of In (indium), Ga (gallium), and Zn (zinc). The ratio between In, Ga, and Zn (composition ratio) is not particularly limited, and includes In:Ga:Zn=2:2:1, In:Ga:Zn=1:1:1, In:Ga:Zn=1:1:2, and the like, for example. Such an oxide semiconductor layer 5 may be made of an oxide semiconductor film containing an In—Ga—Zn—O type semiconductor. Note that a channel-etch type TFT that includes an active layer containing an In—Ga—Zn—O type semiconductor may be referred to as a “CE-OS-TFT”.

The In—Ga—Zn—O type semiconductor may be amorphous or crystalline. As a crystalline In—Ga—Zn—O type semiconductor, a crystalline In—Ga—Zn—O type semiconductor whose c axis is oriented generally perpendicular to the layer plane is preferable.

Note that the crystal structure of a crystalline In—Ga—Zn—O type semiconductor is disclosed in, for example, Japanese Laid-Open Patent Publication No. 2014-007399, supra, Japanese Laid-Open Patent Publication No. 2012-134475, Japanese Laid-Open Patent Publication No. 2014-209727, and so on. The entire disclosure of Japanese Laid-Open Patent Publication No. 2012-134475 and Japanese Laid-Open Patent Publication No. 2014-209727 is incorporated herein by reference. A TFT having an In—Ga—Zn—O type semiconductor layer has a high mobility (more than 20 times that of an a-Si TFT) and a low leak current (less than 1/100 of that of an a-Si TFT), and is suitably used as a driving TFT (e.g., a TFT that is included in a driving circuit which is provided around a displaying region that includes a plurality of pixels and on the same substrate as the displaying region) or a pixel TFT (a TFT which is provided in a pixel).

The oxide semiconductor layer 5 may contain other oxide semiconductors instead of an In—Ga—Zn—O type semiconductor. For example, it may contain an In—Sn—Zn—O type semiconductor (e.g., In₂O₃—SnO₂—ZnO; InSnZnO). An In—Sn—Zn—O type semiconductor is a ternary oxide of In (indium), Sn (tin), and Zn (zinc). Alternatively, the oxide semiconductor layer 5 may contain an In—Al—Zn—O type semiconductor, an In—Al—Sn—Zn—O type semiconductor, a Zn—O type semiconductor, an In—Zn—O type semiconductor, a Zn—Ti—O type semiconductor, a Cd—Ge—O type semiconductor, a Cd—Pb—O type semiconductor, CdO (cadmium oxide), an Mg—Zn—O type semiconductor, an In—Ga—Sn—O type semiconductor, an In—Ga—O type semiconductor, a Zr—In—Zn—O type semiconductor, an Hf—In—Zn—O type semiconductor, an Al—Ga—Zn—O type semiconductor, a Ga—Zn—O type semiconductor, or the like.

<Method of Producing the Semiconductor Device 101>

Next, an exemplary method of producing the semiconductor device 101 will be described.

First, a gate electrode 3 is formed on a substrate 1. As the substrate 1, a glass substrate, a silicon substrate, a plastic substrate (resin substrate) which is thermally resistant, or the like may be used.

The gate electrode 3 is obtained by forming an electrically conductive film for the gate (thickness: not less than 200 nm and not more than 700 nm) on the substrate 1 by a sputtering technique or the like, and patterning it, for example. The material of the electrically conductive film for the gate is not particularly limited; a film containing a metal such as aluminum (Al), tungsten (W), molybdenum (Mo), tantalum (Ta), chromium (Cr), titanium (Ti), or copper (Cu), or an alloy thereof, or a metal nitride thereof (e.g., tantalum nitride (TaN)) may be used as appropriate. The electrically conductive film for the gate may be a multilayer film in which more than one film among these are stacked.

Next, a gate dielectric layer 4 having a multilayer structure is formed so as to cover the gate electrode 3. Specifically, first, as a lower layer 40 of the gate dielectric layer 4, a silicon oxide (SiOx, x>0) film or silicon nitride (SiNx, x>0) film (thickness: e.g. not less than 50 nm and not more than 500 nm) is formed by CVD technique, for example. The film formation temperature is set to e.g. not less than 200° C. and not more than 400° C. Thereafter, as a halogen element-containing dielectric layer 41, an SiOx film or an SiNx film containing a halogen element (thickness: e.g. not less than 50 nm and not more than 500 nm) is formed by CVD technique, for example. A dielectric film containing a halogen element can be formed by adding the halogen element to the source gas. The film formation temperature is set to e.g. not less than 200° C. and not more than 400° C. Herein, as the halogen element-containing dielectric layer 41, a dielectric film (SiOx:F or SiNx:F) containing fluorine atoms is formed by using a source gas containing SiF₄ gas. The halogen element concentration in the film can be adjusted by changing the flow rate of the SiF₄ gas. As the source gas, a gaseous mixture containing a halogen element e.g., nitrogen trifluoride, carbon tetrachloride, and the like, may be used.

Instead of a silicon oxide (SiOx) film or a silicon nitride (SiNx) film, a silicon oxide nitride (SiOxNy; x>y) film, a silicon nitride oxide (SiNxOy; x>y) film, or the like may be used.

Next, on the gate dielectric layer 4, e.g. by sputtering technique, a main-layer oxide semiconductor film (thickness: e.g., not less than 10 nm and not more than 100 nm), from which to form a main layer 50 of an oxide semiconductor layer 5, and an upper halogen element-containing oxide semiconductor film (thickness: e.g. not less than 5 nm and not more than 30 nm), from which to form a first halogen element-containing oxide semiconductor layer 51, are sequentially formed. The main-layer oxide semiconductor film and the upper halogen element-containing oxide semiconductor film may be consecutively formed in a sputtering apparatus. The film formation temperature (substrate temperature) is set to e.g. not less than room temperature and not more than 200° C.

Specifically, as the main-layer oxide semiconductor film, an oxide semiconductor film is first formed by sputtering technique, e.g., an In—Ga—Zn—O type semiconductor film, an In—Sn—Zn—O type semiconductor film, an Al—Ga—Zn—O type semiconductor film, a Ga—Zn—O type semiconductor film, a Zn—Ti—O type semiconductor film, or an In—Zn—O type semiconductor film. As the sputtering target, a metal target or a metal oxide target can be used. The substrate 1 is fixed in a sputtering apparatus, and a noble gas and/or oxygen gas such as Ar gas is introduced in the sputtering apparatus. When introducing a noble gas alone, an oxide target may be used as the sputtering target.

Thereafter, an upper halogen element-containing oxide semiconductor film is formed on the main-layer oxide semiconductor film. The upper halogen element-containing oxide semiconductor film can be formed by using the same sputtering target as that for the main-layer oxide semiconductor film, and by using as the sputtering gas a gaseous mixture including a gas containing a halogen element (which herein is fluorine). This provides a semiconductor film which contains the halogen element in addition to the same component (metallic element) as that in the main-layer oxide semiconductor film.

As the halogen element-containing gas, for example, carbon tetrafluoride (CF₄), sulfur hexafluoride (SF₆), nitrogen trifluoride (NF₃), chlorine (Cl₂), boron trichloride (BCl₃), silicon tetrachloride (SiCl₄), carbon tetrachloride (CCl₄), or the like may be used. As the sputtering gas, a gaseous mixture of such a halogen element-containing gas and oxygen may be used. By controlling the flow rate (i.e., the amount supplied to the substrate) of the halogen element-containing gas, it is possible to adjust the halogen element concentration in the upper halogen element-containing oxide semiconductor film.

Note that the method of forming the upper halogen element-containing oxide semiconductor film is not limited to the above method. For example, a sputtering target to which a halogen element such as fluorine, chlorine, etc., has been added in advance may be used.

Thereafter, the main-layer oxide semiconductor film and the upper halogen element-containing oxide semiconductor film are patterned to give the oxide semiconductor layer 5.

Next, an electrically conductive film for the source (thickness: e.g. not less than 200 nm and not more than 700 nm) is formed so as to cover the oxide semiconductor layer 5, which is patterned to give a source electrode 7s and a drain electrode 7d. The portion of the oxide semiconductor layer 5 that comes in contact with the source electrode 7s defines a source contact region, and the portion that comes in contact with the drain electrode 7d defines a drain contact region. Thus, the TFT 10 is obtained.

The material of the electrically conductive film for the source is not particularly limited; a film containing a metal such as aluminum (Al), tungsten (W), molybdenum (Mo), tantalum (Ta), chromium (Cr), titanium (Ti), or copper (Cu), or an alloy thereof, or a metal nitride thereof (e.g., tantalum nitride (TaN)) may be used as appropriate. The electrically conductive film for the source may be a multilayer film in which more than one film among these are stacked.

Next, a passivation layer 9 (thickness: e.g. not less than 200 nm and not more than 500 nm) is formed so as to cover the TFT 10.

As the passivation layer 9, an inorganic dielectric film (passivation film) such as a silicon oxide (SiOx) film, a silicon nitride (SiNx) film, a silicon oxide nitride (SiOxNy; x>y) film, or a silicon nitride oxide (SiNxOy; x>y) film may be used. The passivation layer 9 may be a multilayer film. Herein, the passivation layer is formed by CVD technique, for example. The film formation temperature may be e.g. not less than 200° C. and not more than 300° C.

After the passivation layer 9 is formed, the entire substrate may be subjected to a heat treatment (annealing). As a result, TFT characteristics can be made more stable. Herein, for example, 1 to 2 hours of heat treatment is performed in an inert gas (a noble gas or nitrogen) ambient at a temperature of not less than 200° C. and not more than 400° C. In this manner, the semiconductor device 101 is produced.

### Second Embodiment

Hereinafter, with reference to the drawings, a second embodiment of a semiconductor device according to the present invention will be described. The semiconductor device of the present embodiment differs from the semiconductor device 101 shown in FIG. 1 in that a halogen element-containing oxide semiconductor layer is formed not only on the passivation layer 9 side of the main layer 50 but also on the gate dielectric layer 4 side. Moreover, in the present embodiment, the gate dielectric layer 4 does not include a halogen element-containing dielectric layer.

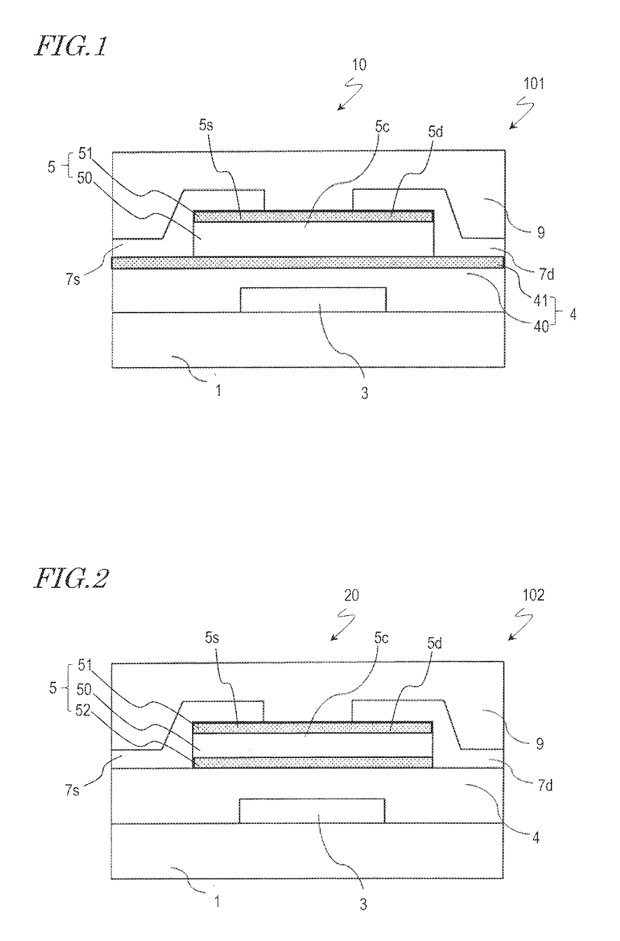

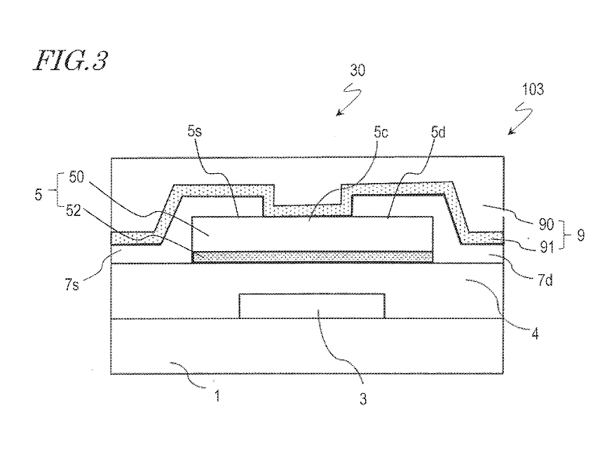

FIG. 2 is a schematic cross-sectional view illustrating a semiconductor device 102. In FIG. 2, any similar constituent elements to those in FIG. 1 are denoted by like reference numerals, with their description being omitted.

The semiconductor device 102 includes a TFT 20 of the channel-etch type. An oxide semiconductor layer 5 of the TFT 20 has a multilayer structure that includes a main layer containing substantially no halogen element, a first halogen element-containing oxide semiconductor layer 51 which is formed between the main layer 50 and the passivation layer 9, and a second halogen element-containing oxide semiconductor layer 52 which is formed between the main layer 50 and the gate dielectric layer 4.

The material, thickness, halogen element concentration, etc., of the main layer 50 are similar to the material, thickness, halogen element concentration, etc., of the main layer 50 in the semiconductor device 101 (FIG. 1) according to the previous embodiment. The material, thickness, halogen element concentration, etc., of the first and second halogen element-containing oxide semiconductor layers 51 and 52 are similar to the material, thickness, halogen element concentration, etc., of the first halogen element-containing oxide semiconductor layer 51 in the semiconductor device 101 (FIG. 1) according to the previous embodiment. Note that the first halogen element-containing oxide semiconductor layer 51 and the second halogen element-containing oxide semiconductor layer 52 may be identical or different in terms of thickness, kind and concentration of halogen element, composition of the oxide semiconductor which is the main component, and so on.

The material, thickness, halogen element concentration, etc., of the gate dielectric layer 4 are similar to the material, thickness, halogen element concentration, etc., of the lower layer 40 (FIG. 1) in the gate dielectric layer 4 according to the previous embodiment. In the present embodiment, the gate dielectric layer 4 does not include a layer containing a halogen element.

The material, thickness, etc., of the other constituent elements, e.g., the gate electrode 3, the source electrode 7s, the drain electrode 7d, and the passivation layer 9, are similar to those in the previous embodiment (FIG. 1).

According to the present embodiment, the halogen element included the first halogen element-containing oxide semiconductor layer 51 and the second halogen element-containing oxide semiconductor layer 52 can terminate an impurity level that occurs in the oxide semiconductor layer 5 (especially in the main layer 50), thus compensating for oxygen defects. This allows to suppress fluctuations in the TFT characteristics, and enhance reliability of the TFT 10.

Moreover, the halogen element diffuses from the first halogen element-containing oxide semiconductor layer 51 toward the upper face of the main layer 50 of the oxide semiconductor layer 5, and the halogen element diffuses from the second halogen element-containing oxide semiconductor layer 52 toward the lower face of the main layer 50. This allows to effectively suppress fluctuations in the TFT characteristics that may arise because of the upper face and the lower face of the oxide semiconductor layer being in contact with the dielectric layers (the gate dielectric layer 4 and the passivation layer 9).

Furthermore, since the second halogen element-containing oxide semiconductor layer 52, the main layer 50, and the first halogen element-containing oxide semiconductor layer 51 can be successively formed in a sputtering apparatus, an impurity level and oxygen defects due to process damage can be more effectively restrained from occurring in the main layer 50 because of the fabrication process.

The first halogen element-containing oxide semiconductor layer 51 may constitute the upper face of the oxide semiconductor layer 5, thus being in contact with the passivation layer 9. The second halogen element-containing oxide semiconductor layer 52 may constitute the lower face of the oxide semiconductor layer 5, thus being in contact with the gate dielectric layer 4. This will suppress changes in the state of the main layer 50 that are associated with the passivation layer 9 and the gate dielectric layer 4 more effectively.

Note that the oxide semiconductor layer 5 may at least include the second halogen element-containing oxide semiconductor layer 52, the main layer 50, and the first halogen element-containing oxide semiconductor layer 51, and may have a multilayer structure of four or more layers. For example, the main layer 50 may include a plurality of oxide semiconductor layers differing with respect to their compositions, crystal states, or the like.

<Method of Producing the Semiconductor Device 102>

Next, an exemplary method of producing the semiconductor device 102 will be described. When the material, thickness, formation process, etc., of any layer or film in the semiconductor device 102 are similar to those in the semiconductor device 101 (FIG. 1), their description will occasionally be omitted.

First, a gate electrode 3 is formed on a substrate 1. Next, a gate dielectric layer 4 containing substantially no halogen element is formed so as to cover the gate electrode 3. As the gate dielectric layer 4, a silicon oxide (SiOx) layer, a silicon nitride (SiNx) layer, a silicon oxide nitride (SiOxNy; x>y) layer, a silicon nitride oxide (SiNxOy; x>y) layer, or the like may be used as appropriate. The gate dielectric layer 4 may have a multilayer structure. For example, it may have a multilayer structure with a lower layer of a silicon nitride (SiNx, x>0) film and an upper layer of a silicon oxide (SiOx, x>0) film.

Next, on the gate dielectric layer 4, an oxide semiconductor layer 5 having a multilayer structure is formed. Herein, first, a lower oxide semiconductor film (thickness: e.g. not less than 5 nm and not more than 30 nm) from which to form a second halogen element-containing oxide semiconductor layer 52 is formed. Next, a main-layer oxide semiconductor film (thickness: e.g., not less than 10 nm and not more than 100 nm) and an upper oxide semiconductor film (thickness: e.g. not less than 5 nm and not more than 30 nm) from which to form a first halogen element-containing oxide semiconductor layer 51 are formed in this order. These oxide semiconductor films may be successively formed in a sputtering apparatus. The kinds, thicknesses, the formation methods, etc., of the upper and lower halogen element-containing oxide semiconductor films may be similar to those of the upper halogen element-containing oxide semiconductor film in the previous embodiment. Thereafter, the resultant multilayer film is patterned to give the oxide semiconductor layer 5.

Next, a source electrode 7s, a drain electrode 7d, and a passivation layer 9 are formed by a similar method to those in the previous embodiment, followed by a heat treatment. In this manner, the semiconductor device 102 is obtained.

### Third Embodiment

Hereinafter, with reference to the drawings, a third embodiment of a semiconductor device according to the present invention will be described. In the semiconductor device of the present embodiment, a halogen element-containing oxide semiconductor layer is formed on the gate dielectric layer 4 side of the main layer 50. Moreover, the gate dielectric layer 4 does not include a halogen element-containing dielectric layer, but instead, a passivation layer 9 includes a dielectric layer containing a halogen element.

FIG. 3 is a schematic cross-sectional view illustrating a semiconductor device 103. In FIG. 3, any similar constituent elements to those in FIG. 1 and FIG. 2 are denoted by like reference numerals, with their description being omitted.

The semiconductor device 103 includes a TFT 30 of the channel-etch type. An oxide semiconductor layer 5 of the TFT 30 has a multilayer structure that includes a main layer 50 containing substantially no halogen element and a second halogen element-containing oxide semiconductor layer 52 which is formed between the main layer 50 and the gate dielectric layer 4.

The passivation layer 9 may have a multilayer structure that includes an upper layer 90 containing substantially no halogen element and a halogen element-containing passivation layer 91 containing a halogen element, the halogen element-containing passivation layer 91 being formed between the upper layer 90 and the oxide semiconductor layer 5. Although not particularly limited, the halogen element may be fluorine, chlorine, or the like, for example. The halogen element-containing passivation layer 91 may contain two or more kinds of halogen elements. The halogen element(s) contained in the halogen element-containing passivation layer 91 may be the same as or different from the halogen element contained in the aforementioned second halogen element-containing oxide semiconductor layer 52.

The upper layer 90 and the halogen element-containing passivation layer 91 may contain the same electrically insulating material as a main component. For example, each of the upper layer 90 and the halogen element-containing passivation layer 91 may mainly contain silicon oxide (SiOx) or silicon nitride (SiNx). Note that the passivation layer 9 may at least include the halogen element-containing passivation layer 91; it may be composed only of the halogen element-containing passivation layer 91, or have a multilayer structure of three or more layers.

The material, thickness, etc., of the other constituent elements, e.g., the gate electrode 3, the gate dielectric layer 4, the source electrode 7s, and the drain electrode 7d, are similar to those in the semiconductor device 102 according to the second embodiment (FIG. 2).

According to the present embodiment, the halogen element(s) contained in the halogen element-containing passivation layer 91 and the second halogen element-containing oxide semiconductor layer 52 can terminate an impurity level that occurs in the oxide semiconductor layer 5 (especially in the main layer 50), thus compensating for oxygen defects. This allows to suppress fluctuations in the TFT characteristics, and enhance reliability of the TFT 10.

Moreover, the halogen element(s) diffuses from the halogen element-containing passivation layer 91 toward the upper face of the main layer 50 of the oxide semiconductor layer 5, and the halogen element diffuses from the second halogen element-containing oxide semiconductor layer 52 toward the lower face of the main layer 50. As a result, fluctuations in the TFT characteristics that may arise because of the upper face and the lower face of the oxide semiconductor layer being in contact with the dielectric layers (i.e., the gate dielectric layer 4 and the passivation layer 9) can be suppressed more effectively.

Furthermore, since the second halogen element-containing oxide semiconductor layer 52 and the main layer 50 can be successively formed in a sputtering apparatus, defects can be more effectively restrained from occurring in the main layer 50 because of the fabrication process.

The halogen element-containing passivation layer 91 may constitute a lower face of the passivation layer 9, thus being in contact with the oxide semiconductor layer 5. This will suppress changes in the state of the main layer 50 that are associated with the passivation layer 9 more effectively.

<Method of Producing the Semiconductor Device 103>

Next, an exemplary method of producing the semiconductor device 103 will be described. When the material, thickness, formation process, etc., of any layer or film in the semiconductor device 103 are similar to those in the semiconductor device 102 (FIG. 2), their description will occasionally be omitted.

First, a gate electrode 3 is formed on a substrate 1. Next, a gate dielectric layer 4 containing substantially no halogen element is formed so as to cover the gate electrode 3.

Next, an oxide semiconductor layer 5 having a multilayer structure is formed on the gate dielectric layer 4. Herein, first, an oxide semiconductor film (lower halogen element-containing oxide semiconductor film) (thickness: e.g. not less than 5 nm and not more than 30 nm) from which to form a second halogen element-containing oxide semiconductor layer 52 and a main-layer oxide semiconductor film (thickness: e.g., not less than 10 nm and not more than 100 nm) are formed in this order. These oxide semiconductor films may be successively formed in a sputtering apparatus. The material and formation method of each oxide semiconductor film (i.e., the lower halogen element-containing oxide semiconductor film and the main-layer oxide semiconductor film) are similar to those in the second embodiment described above. Thereafter, the resultant multilayer film is patterned to give the oxide semiconductor layer 5.

Next, a source electrode 7s and a drain electrode 7d are formed by a similar method to those in an earlier embodiment, whereby a TFT 103 is obtained.

Thereafter, a passivation layer 9 covering the TFT 103 is formed. Specifically, as a halogen element-containing passivation layer 91, an SiOx film or SiNx film (thickness: e.g. not less than 5 nm and not more than 30 nm) containing a halogen element is first formed by CVD technique, for example. A dielectric film containing a halogen element can be formed by adding the halogen element to the source gas. The film formation temperature is set to e.g. not less than 200° C. and not more than 400° C. Herein, as the halogen element-containing passivation layer 91, a dielectric film (SiOx:F or SiNx:F) containing fluorine atoms is formed by using a source gas containing SiF₄ gas. The halogen element concentration in the film can be adjusted by changing the flow rate of the SiF₄ gas. Thereafter, as an upper layer 90 of the passivation layer 9, an SiOx (x>0) film or an SiNx (x>0) film (thickness: e.g. not less than 200 nm and not more than 500 nm) is formed by CVD technique, for example. The film formation temperature is set to e.g. not less than 200° C. and not more than 400° C. The thickness of the upper layer 90 may be set larger than that of the halogen element-containing passivation layer 91.

Note that, instead of a silicon oxide (SiOx) film or a silicon nitride (SiNx) film, a silicon oxide nitride (SiOxNy; x>y) film, a silicon nitride oxide (SiNxOy; x>y) film, or the like may be used.

After the passivation layer 9 is formed, a heat treatment is performed by a similar method to that of an earlier embodiment. In this manner, the semiconductor device 103 is obtained.

### Examples and Comparative Example

TFTs according to Examples and Comparative Example were produced, and their reliability was evaluated. The method and results thereof will be described.

As Example 1, a TFT of the same structure as the TFT 10 (FIG. 1) according to the first embodiment is used; and, as Example 2, a TFT of the same structure as the TFT 20 (FIG. 2) according to the second embodiment is used. As Comparative Example, a TFT having no halogen element added thereto is used. The TFT according to Comparative Example is similar in structure to the TFT according to Example 1 except that the upper layer of the gate dielectric layer and the upper layer of the oxide semiconductor layer contain no halogen element. In the TFTs according to Examples 1 and 2 and Comparative Example, the channel width W is 20 μm, and the channel length L is 7 μm.

These TFTs are subjected to a PBTI (Positive Bias Temperature Instability) test. The test is conducted at a temperature of 60° C., with a gate voltage (gate-source voltage) Vgs of +30 V and a drain voltage (drain-source voltage) Vd of +10 V. The stressing time is 10000 seconds.

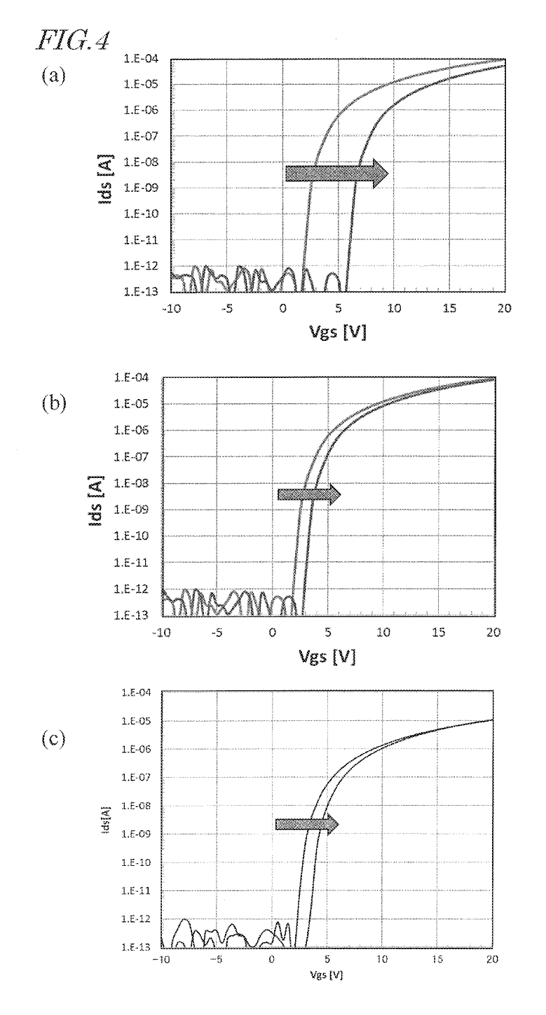

FIGS. 4(a) to (c) are graphs showing current-voltage characteristics before and after a PBTI test in TFTs according to Comparative Example and Examples 1 and 2, respectively.

It can be confirmed from these results that a variation ΔVth the post-test threshold voltage from the threshold voltage at an initial period of the test is kept lower in the TFTs according to Examples 1 and 2 than in the TFT according to Comparative Example, indicative of an improved reliability.

The variations ΔVth in the threshold voltages of the TFTs according to Examples 1 and 2 are substantially the same. Although not shown, the TFT 103 (FIG. 3) similarly provides an effect of reducing ΔVth.

The semiconductor devices according to embodiments of the present invention are not limited to the semiconductor devices shown in FIG. 1 to FIG. 3. It suffices if a halogen element-containing oxide semiconductor layer is formed on at least one of two opposite principal faces of the main layer of the oxide semiconductor layer 5, and it is not necessary for any dielectric layer that is in contact with the oxide semiconductor layer 5 to contain a halogen element.

TFTs according to the present embodiments may have a channel etch structure, or an etchstop structure with an etchstop that covers the channel region.

In a “TFT of the channel-etch type”, as shown in FIG. 1 to FIG. 3, no etchstop layer is formed over the channel region 5c, and lower faces of the edges of the source electrode 7s and the drain electrode 7d that are closer to the channel are disposed in contact with the upper face of the oxide semiconductor layer 5. A TFT of the channel-etch type is formed by, for example, forming an electrically conductive film for the source/drain electrodes on the oxide semiconductor layer 5, followed by source-drain separation. In the source-drain separation step, a surface portion of the channel region may be etched.

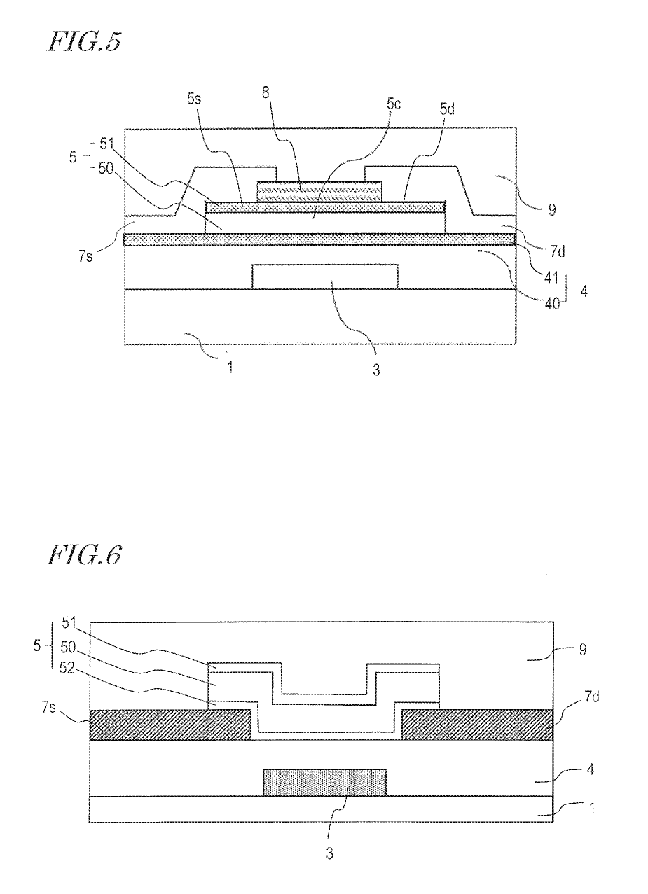

On the other hand, in a TFT of the etchstop type, as illustrated in FIG. 5, an etchstop layer (dielectric layer) 8 is formed so as to cover at least the channel region 5c of the oxide semiconductor layer 5. The lower faces of the edges of the source electrode 7s and the drain electrode 7d that are closer to the channel are located above the etchstop layer 8, for example. A TFT of the etchstop type is formed by, for example, after forming an etchstop layer 8 that covers a portion of the oxide semiconductor layer 5 to become the channel region 5c, forming an electrically conductive film for the source/drain electrode over the oxide semiconductor layer 5 and the etchstop layer 8, and performing source-drain separation. In a TFT of the etchstop type, the lower face of the oxide semiconductor layer 5 is in contact with e.g. the gate dielectric layer 4, whereas the upper face of the oxide semiconductor layer 5 is in contact with the etchstop layer 8. In the example shown in the figure, a first halogen element-containing oxide semiconductor layer 51 is formed between the main layer 50 of the oxide semiconductor layer 5 and the etchstop layer 8. Moreover, the gate dielectric layer 4 includes a halogen element-containing dielectric layer 41. Note that the construction of the TFT of the etchstop type is not limited to this example. It suffices so long as a halogen element-containing oxide semiconductor layer(s) is formed between the main layer 50 of the oxide semiconductor layer 5 and the gate dielectric layer 4 and/or the etchstop layer 8. In the case where no halogen element-containing oxide semiconductor layer is formed above the main layer 50, the etchstop layer 8 may include a halogen element-containing dielectric layer.

In the examples shown in FIG. 1 to FIG. 3 and FIG. 5, the TFT has a top-contact structure where the source and drain electrodes 7s and 7d are in contact with the upper face of the oxide semiconductor layer 5; however, it may be of a bottom-contact structure such that they are in contact with the lower face of the oxide semiconductor layer 5. In a TFT having a bottom-contact structure, as illustrated in FIG. 6, the source and drain electrodes 7s and 7d are interposed between the oxide semiconductor layer 5 and the gate dielectric layer 4. Otherwise its construction may be similar to that of the TFTs shown in FIG. 1 to FIG. 3 (i.e., in this example, the TFT 20 shown in FIG. 2).

Furthermore, in the TFTs shown in FIG. 1 to FIG. 3, FIG. 5, and FIG. 6, the gate electrode 3 is disposed on the substrate 1 side of the oxide semiconductor layer 5 (i.e., bottom-gate structure); however, the gate electrode 3 may be disposed above the oxide semiconductor layer 5 (i.e., top gate structure). In a TFT having a top gate structure, for example, the lower face of the oxide semiconductor layer is in contact with an underlying dielectric layer that is formed on the substrate, whereas the upper face of the oxide semiconductor layer is in contact with the gate dielectric layer. In this case, too, it suffices so long as a halogen element-containing oxide semiconductor layer is formed between the main layer of the oxide semiconductor layer and the gate dielectric layer and/or the underlying dielectric layer. In the case where no halogen element-containing oxide semiconductor layer is formed below the main layer, the underlying dielectric layer may include a halogen element-containing dielectric layer.

Furthermore, embodiments of the present invention are not limited to devices that include TFTs, but are also applicable to other semiconductor devices in which an oxide semiconductor layer is used (e.g., devices that include thin film diodes).

### Fourth Embodiment

Hereinafter, with reference to the drawings, a fourth embodiment of a semiconductor device according to the present invention will be described. The semiconductor device of the present embodiment is an active matrix substrate which includes an oxide semiconductor TFT and a crystalline silicon TFT that are formed on the same substrate.

The active matrix substrate has a TFT (pixel TFT) for each pixel. As the pixel TFT, an oxide semiconductor TFT whose active layer is e.g. an In—Ga—Zn—O type semiconductor film is used.

In some cases, a part or a whole of a peripheral driving circuit may be integrally formed on the same substrate as the pixel TFTs. Such an active matrix substrate is referred to as a driver-monolithic active matrix substrate. In a driver-monolithic active matrix substrate, the peripheral driving circuit is to be provided in a region (a non-display region or a frame region) other than the region that contains a plurality of pixels (display region). As the TFTs composing the peripheral driving circuit (circuit TFTs), for example, crystalline silicon TFTs whose active layer is a polycrystalline silicon film may be used. Thus, by using oxide semiconductor TFTs as the pixel TFTs and crystalline silicon TFTs as the circuit TFTs, it becomes possible to reduce power consumption in the displaying region and also reduce the frame region in size.

As the pixel TFTs, the TFTs which have been described above with reference to FIG. 1 to FIG. 3, FIG. 5, and FIG. 6 can be applied. This point will be discussed later.

Next, a more specific construction for an active matrix substrate according to the present embodiment will be described with reference to the drawings.

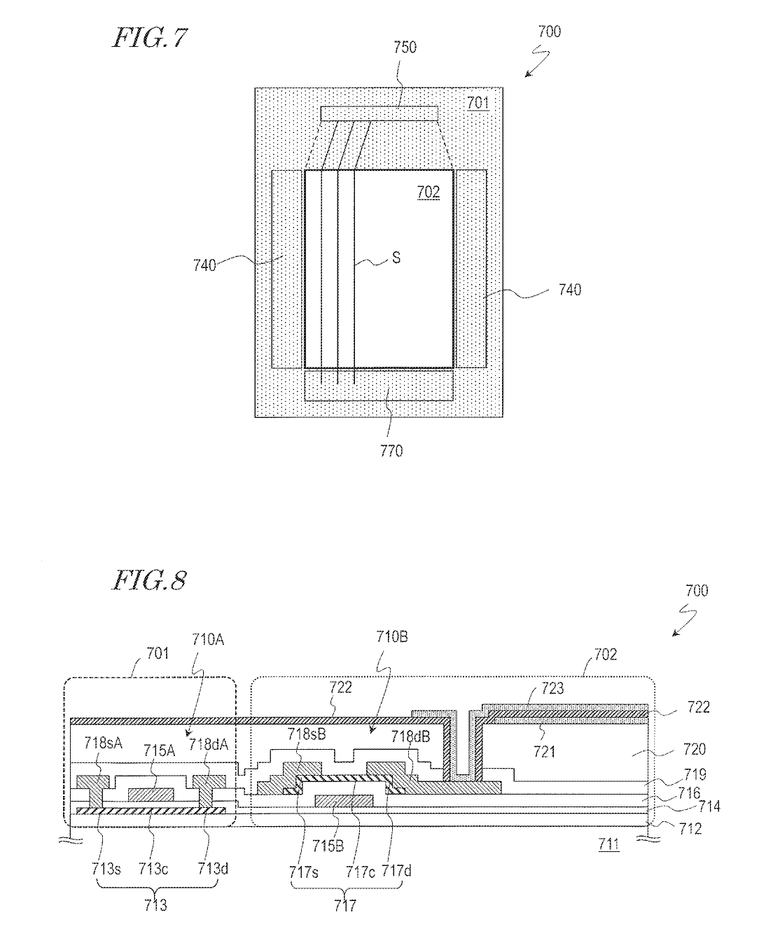

FIG. 7 is a schematic plan view showing an exemplary planar structure of an active matrix substrate 700 according to the present embodiment. FIG. 8 is a cross-sectional view of a crystalline silicon TFT (hereinafter referred to as the “first thin film transistor”) 710A and an oxide semiconductor TFT (hereinafter referred to as the “second thin film transistor”) 710B in the active matrix substrate 700.

As shown in FIG. 7, the active matrix substrate 700 has a display region 702 including a plurality of pixels and a region (non-display region) other than the display region 702. The non-display region includes a driving circuit forming region 701 in which driving circuitry is provided. In the driving circuit forming region 701, gate driver circuits 740, a check circuit 770, and the like are provided, for example. In the display region 702, a plurality of gate bus lines (not shown) extending along the row direction and a plurality of source bus lines S extending along the column direction are formed. Although not shown, each pixel is defined by a gate bus line and a source bus line S, for example. The gate bus lines are respectively connected to the terminals of the gate driver circuits. The source bus lines S are respectively connected to the terminals of a driver IC 750 that is mounted on the active matrix substrate 700.

As shown in FIG. 8, in the active matrix substrate 700, a second thin film transistor 710B is formed as a pixel TFT for each pixel in the display region 702, whereas first thin film transistors 710A are formed as circuit TFTs in the driving circuit forming region 701.

The active matrix substrate 700 includes a substrate 711, an underlying film 712 formed on the surface of the substrate 711, a first thin film transistor 710A formed on the underlying film 712, and a second thin film transistor 710B formed on the underlying film 712. The first thin film transistor 710A is a crystalline silicon TFT having an active region that mainly contains crystalline silicon. The second thin film transistor 710B is an oxide semiconductor TFT having an active region that mainly contains an oxide semiconductor. The first thin film transistor 710A and the second thin film transistor 710B are fabricated in an integral manner into the substrate 711. As used herein, within the semiconductor layer to become an active layer of a TFT, an “active region” refers to a region where a channel is to be formed.

The first thin film transistor 710A includes a crystalline silicon semiconductor layer (e.g., a low-temperature polysilicon layer) 713 formed on the underlying film 712, a first dielectric layer 714 covering the crystalline silicon semiconductor layer 713, and a gate electrode 715A provided on the first dielectric layer 714. The portion of the first dielectric layer 714 that is located between the crystalline silicon semiconductor layer 713 and the gate electrode 715A functions as a gate insulating film of the first thin film transistor 710A. The crystalline silicon semiconductor layer 713 has a region (active region) 713c in which a channel is to be formed, and a source region 713s and a drain region 713d respectively located on opposite sides of the active region. In this example, a portion of the crystalline silicon semiconductor layer 713 that overlaps the gate electrode 715A via the first dielectric layer 714 defines the active region 713c. The first thin film transistor 710A also includes a source electrode 718sA and a drain electrode 718dA which are respectively connected to the source region 713s and the drain region 713d. The source and drain electrodes 718sA and 718dA may be provided on an interlevel dielectric film (which herein is a second dielectric layer 716) covering the gate electrode 715A and the crystalline silicon semiconductor layer 713, and connected to the crystalline silicon semiconductor layer 713 within contact holes which are formed in the interlevel dielectric film.

The second thin film transistor 710B includes a gate electrode 715B provided on the underlying film 712, a second dielectric layer 716 covering the gate electrode 715B, and an oxide semiconductor layer 717 on the second dielectric layer 716. As shown in the figure, the first dielectric layer 714, which is the gate insulating film of the first thin film transistor 710A, may extend to the region where the second thin film transistor 710B is to be formed. In this case, the oxide semiconductor layer 717 may be formed on the first dielectric layer 714. A portion of the second dielectric layer 716 that is located between the gate electrode 715B and the oxide semiconductor layer 717 functions as a gate insulating film of the second thin film transistor 710B. The oxide semiconductor layer 717 has a region (active region) 717c in which a channel is to be formed, and a source contact region 717s and a drain contact region 717d respectively located on opposite sides of the active region. In this example, a portion of the oxide semiconductor layer 717 that overlaps the gate electrode 715B via the second dielectric layer 716 defines the active region 717c. Moreover, the second thin film transistor 710B further includes a source electrode 718sB and a drain electrode 718dB which are respectively connected to the source contact region 717s and the drain contact region 717d. Note that a construction in which no underlying film 712 is formed on the substrate 711 would also be possible.

The thin film transistors 710A and 710B are covered by a passivation film 719 and a planarization film 720. In each second thin film transistor 710B functioning as a pixel TFT, the gate electrode 715B is connected to a gate bus line (not shown), the source electrode 718sB is connected to a source bus line (not shown), and the drain electrode 718dB is connected to the pixel electrode 23. In this example, the drain electrode 718dB is connected to the corresponding pixel electrode 23 within an opening which is formed in the passivation film 719 and the planarization film 720. A video signal is supplied to the source electrode 718sB via the source bus line, and a necessary charge is written to the pixel electrode 23 based on a gate signal from the gate bus line.

As shown in the figure, a transparent conductive layer 721 may be formed as a common electrode on the planarization film 720, and a third dielectric layer 22 may be formed between the transparent conductive layer (common electrode) 721 and the pixel electrodes 723. In this case, the pixel electrodes 723 may have slit apertures. The active matrix substrate 700 as such may be applicable to a display device of an FFS (Fringe Field Switching) mode, for example. An FFS mode is a mode under the lateral field method, in which a pair of electrodes are provided on one substrate and an electric field is applied to liquid crystal molecules in a direction (lateral direction) that is parallel to the substrate plane. In this example, an electric field is created as represented by electric lines of force which go out from the pixel electrode 723, pass through the liquid crystal layer (not shown), and further through the slit apertures in the pixel electrode 723 to emerge on the common electrode 721. This electric field includes a component in a lateral direction to the liquid crystal layer. As a result, an electric field in the lateral direction can be applied to the liquid crystal layer. In the lateral field method, liquid crystal molecules do not erect from the substrate, thus providing an advantage of being able to provide a wider viewing angle than in the vertical field method.

As the second thin film transistor 710B according to the present embodiment, the TFTs according to the first to third embodiments described above with reference to FIGS. 1 to 3 and FIG. 5 can be used. When the TFT 101 to 103 in FIG. 1 to FIG. 3 are applied, the gate electrode 3, the gate dielectric layer 4, the oxide semiconductor layer 5, and the source and drain electrodes 7s and 7d of the TFTs 101 to 103 may be allowed to correspond to, respectively, the gate electrode 715B, the second dielectric layer (gate dielectric layer) 716, the oxide semiconductor layer 717, and the source and drain electrodes 718sB and 718dB shown in FIG. 8.

As a TFT (check TFT) in the check circuit 770 shown in FIG. 7, the thin film transistor 710B, which is an oxide semiconductor TFT, may be used.

Although not shown, the check TFT(s) and the check circuit may be formed in the region where the driver IC 750 shown in FIG. 7 is mounted, for example. In this case, the check TFT is interposed between the driver IC 750 and the substrate 711.

In the example shown in the figure, the first thin film transistor 710A has a top gate structure in which the crystalline silicon semiconductor layer 713 is disposed between the gate electrode 715A and the substrate 711 (or the underlying film 712). On the other hand, the second thin film transistor 710B has a bottom gate structure in which the gate electrode 715B is disposed between the oxide semiconductor layer 717 and the substrate 711 (or the underlying film 712). By adopting such a structure, when forming the two types of thin film transistors 710A and 710B in an integral manner on the same substrate 711, it is possible to more effectively suppress increase in the number of production steps and the production cost.

The TFT structures of the first thin film transistor 710A and the second thin film transistor 710B are not limited to the above. For example, the thin film transistors 710A and 710B may have the same TFT structure. Alternatively, the first thin film transistor 710A may have a bottom gate structure while the second thin film transistor 710B may have a top gate structure. In the case of a bottom-gate structure, it may be of the channel-etch type as is the thin film transistor 710B, or of the etchstop type.

The second dielectric layer 716, which is the gate insulating film of the second thin film transistor 710B, may be allowed to extend to the region where the first thin film transistor 710A is formed, so as to function as an interlevel dielectric film covering the gate electrode 715A and the crystalline silicon semiconductor layer 713 of the first thin film transistor 710A. When the interlevel dielectric film of the first thin film transistor 710A and the gate insulating film of the second thin film transistor 710B are thus formed in the same layer (second dielectric layer) 716, the second dielectric layer 716 may have a multilayer structure. For example, the second dielectric layer 716 may have a multilayer structure that includes a hydrogen donor layer (e.g., a silicon nitride layer) capable of supplying hydrogen and an oxygen donor layer (e.g., a silicon oxide layer) capable of supplying oxygen and disposed on the hydrogen donor layer.

The gate electrode 715A of the first thin film transistor 710A and the gate electrode 715B of the second thin film transistor 710B may be formed in the same layer. Moreover, the source and drain electrodes 718sA and 718dA of the first thin film transistor 710A and the source and drain electrodes 718sB and 718dB of the second thin film transistor 710B may be formed in the same layer. Being “formed in the same layer” means being formed by using the same film (conductive film). As a result, increase in the number of production steps and the production cost can be suppressed.

### INDUSTRIAL APPLICABILITY

Embodiments of the present invention are broadly applicable to oxide semiconductor TFTs and various semiconductor devices having oxide semiconductor TFTs. For example, they are applicable to circuit boards such as active matrix substrates; display devices such as liquid crystal display devices, organic electroluminescence (EL) display devices, and inorganic electroluminescence display devices; imaging devices such as image sensor devices; image input devices; fingerprint reader devices; and also electronic devices such as semiconductor memory.

### REFERENCE SIGNS LIST

1 substrate
3 gate electrode
4 gate dielectric layer
5 oxide semiconductor layer
5s source contact region
5d drain contact region
5c channel region
7s source electrode
7d drain electrode
9 passivation layer
40 lower layer of gate dielectric layer
41 halogen element-containing dielectric layer
50 main layer of oxide semiconductor layer
51, 52 halogen element-containing oxide semiconductor layer
90 upper layer of passivation layer
91 halogen element-containing passivation layer
10, 20, 30 oxide semiconductor TFT
101, 102, 103 semiconductor device

1. A semiconductor device comprising:
a substrate;
an oxide semiconductor layer supported on the substrate, the oxide semiconductor layer having a first principal face and a second principal face opposite to each other; and
a first dielectric layer disposed in contact with the first principal face of the oxide semiconductor layer, wherein
the oxide semiconductor layer has a multilayer structure that includes
a main layer containing substantially no halogen element and
a first halogen element-containing oxide semiconductor layer containing a halogen element, the first halogen element-containing oxide semiconductor layer being interposed between the main layer and the first dielectric layer.

2. The semiconductor device of claim 1, further comprising a second dielectric layer disposed in contact with the second principal face of the oxide semiconductor layer, wherein
the second dielectric layer includes a halogen element-containing dielectric layer containing a halogen element.

3. The semiconductor device of claim 1, further comprising a second dielectric layer which is disposed in contact with the second principal face of the oxide semiconductor layer, wherein
the multilayer structure of the oxide semiconductor layer further includes a second halogen element-containing oxide semiconductor layer containing a halogen element, the second halogen element-containing oxide semiconductor layer interposed between the main layer and the second dielectric layer.

4. The semiconductor device of claim 2 or 3, further comprising: a thin film transistor having the oxide semiconductor layer as an active layer; and a passivation layer which covers the thin film transistor, wherein
the first dielectric layer is the passivation layer; and
the second dielectric layer is a gate dielectric layer of the thin film transistor.

5. The semiconductor device of claim 2, further comprising: a thin film transistor having the oxide semiconductor layer as an active layer; and a passivation layer which covers the thin film transistor, wherein,
the first dielectric layer is a gate dielectric layer of the thin film transistor; and
the second dielectric layer is the passivation layer.

6. The semiconductor device of claim 1, wherein the first halogen element-containing oxide semiconductor layer has a halogen element concentration which is greater than 1×10¹⁸/cm³ but not greater than 1×10²⁰/cm³.

7. The semiconductor device of claim 1, wherein the main layer of the oxide semiconductor layer has a halogen element concentration which is not more than 10¹⁶/cm³.

8. The semiconductor device of claim 1, wherein the first halogen element-containing oxide semiconductor layer has a thickness which is not less than 5 nm and not more than 30 nm.

9. The semiconductor device of claim 1, further comprising a thin film transistor having the oxide semiconductor layer as an active layer, wherein the thin film transistor has a channel etch structure.

10. The semiconductor device of claim 1, wherein the oxide semiconductor layer comprises an In—Ga—Zn—O type semiconductor.

11. The semiconductor device of claim 10, wherein the oxide semiconductor layer includes a crystalline portion.

12. A method of producing a semiconductor device, comprising:
(A) a step of providing a substrate having a dielectric layer on a surface;
(B) a step of forming an oxide semiconductor layer so as to be in contact with the dielectric layer; and
(C) a step of forming another dielectric layer so as to be in contact with an upper face of the oxide semiconductor layer, wherein,
the oxide semiconductor layer has a multilayer structure that includes a main layer containing substantially no halogen element and a halogen element-containing oxide semiconductor layer containing a halogen element; and
step (B) comprises
step (B1) of forming the main layer by a sputtering technique using a target containing a metal or a metal oxide, and
step (B2), which is performed before or after step (B1), of forming the halogen element-containing oxide semiconductor layer by a sputtering technique using the target while supplying a gas containing the halogen element to the substrate.

13. The method of producing a semiconductor device of claim 12, wherein,
step (B2) is performed after step (B1); and
step (A) comprises a step of forming a halogen element-containing dielectric layer containing a halogen element.

14. The method of producing a semiconductor device of claim 12, wherein,
step (B2) is performed before step (B1); and
step (C) comprises a step of forming a halogen element-containing dielectric layer containing a halogen element.

15. The method of producing a semiconductor device of claim 12, wherein,
step (B2) is performed before step (B1);
step (B) further comprises step (B3) of forming, after step (B1), another halogen element-containing oxide semiconductor layer containing a halogen element by a sputtering technique using the target while supplying a gas containing the halogen element to the substrate; and
the multilayer structure of the oxide semiconductor layer includes the halogen element-containing oxide semiconductor layer, the main layer, and the other halogen element-containing oxide semiconductor layer in this order.

16. The method of producing a semiconductor device of claim 12, wherein the semiconductor device comprises a thin film transistor having the oxide semiconductor layer as an active layer.

17. The method of producing a semiconductor device of claim 16, wherein the thin film transistor has a channel etch structure.

18. The method of producing a semiconductor device of claim 12, wherein the oxide semiconductor layer comprises an In—Ga—Zn—O type semiconductor.

19. The method of producing a semiconductor device of claim 18, wherein the oxide semiconductor layer includes a crystalline portion.
